(19) United States
(12) Patent Application Publication
(10) Pub. No.: US 2007/0107750 A1
(43) Pub. Date: May 17, 2007

(54) Method of using NF3 for removing surface deposits from the interior of chemical vapor deposition chambers

(76) Inventors: Herbert H. Sawin, Chestnut Hill, MA (US); Bo Bai, Cambridge, MA (US); Ju Jin An, Cambridge, MA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/593,960

(22) Filed: Nov. 7, 2006

Related U.S. Application Data
(60) Provisional application No. 60/736,430, filed on Nov. 14, 2005.

(51) Int. Cl. B08B 6/00; C09K 13/00; C23C 16/00

(52) U.S. Cl. 134/1.1; 252/79.1; 118/723 R

(57) ABSTRACT

The present invention relates to a remote plasma cleaning method for removing surface deposits from a surface, such as the interior of a depositions chamber that is used in fabricating electronic devices. The process involves activating a gas stream comprising an oxygen source, NF₃, and a fluorocarbon and contacting the activated gas mixture with surface deposits to remove the surface deposits.

### FIELD OF THE INVENTION

The present invention relates to method for removing surface deposits by using an activated gas mixture created by remotely activating a gas mixture comprising an oxygen source, NF₃ and a fluorocarbon. More specifically, this invention relates to methods for removing surface deposits from the interior of a chemical vapor deposition chamber by using an activated gas mixture created by remotely activating a gas mixture comprising an oxygen source, NF₃ and a fluorocarbon.

### BACKGROUND OF THE INVENTION

One of the problems facing operators of chemical vapor deposition chambers is the need to regularly clean the chamber to remove deposits from the chamber walls and platens. This cleaning process reduces the productive capacity of the chamber since the chamber is out of active service during a cleaning cycle. The cleaning process may include, for example, the evacuation of reactant gases and their replacement with a cleaning gas followed by a flushing step to remove the cleaning gas from the chamber using an inert carrier gas. The cleaning gases typically work by etching the contaminant build-ups from the interior surfaces, thus the etching rate of the cleaning gas is an important parameter in the utility and commercial use of the gases. Present cleaning gases are believed to be limited in their effectiveness due to low etch rates. In order to partially obviate this limitation, current gases need to be run at an inefficient flow rate, e.g. at a high flow rate, and thus greatly contribute to the overall operating cost of the CVD reactor and thus, the production cost of the CVD wafer products. Further, increases in pressure result in lower etch rates. For example, U.S. Pat. No. 6,449,521 discloses a mixture of 54% oxygen, 40% perfluoroethane and 6% NF₃ as a cleaning gas for CVD chambers. Kastenmeier, et al. in Journal of Vacuum Science & Technology A 16 (4), 2047 (1998) disclose etching silicon nitride in a CVD chamber using a mixture of NF₃ and oxygen as a cleaning gas. K. J. Kim et al, in Journal of Vacuum Science & Technology B 22 (2), 483 (2004) disclose etching silicon nitride in a CVD chamber adding nitrogen or argon to mixtures of perfluorotetrahydrofuran and oxygen. None of these references disclose etch rates as high as, or over the wide range of pressures, as the instant invention. Thus, there is a need in the art to reduce the operating costs of a CVD reactor with an effective cleaning gas that has a high etch rate and can operate over a wide range of pressures.

### BRIEF SUMMARY OF THE INVENTION

The present invention provides an effective method for cleaning a CVD chamber using a cleaning gas with a high etch rate and that is also effective over a wide range of pressures. The present invention relates to a method of removing surface deposits comprising activating in a remote chamber or in a process chamber, a gas mixture comprising an oxygen source, a fluorocarbon, and NF₃ wherein the molar ratio of oxygen:fluorocarbon is at least 0.75:1. The gas mixtures can be activated by an RF source using sufficient power for a sufficient time such that said gas mixture reaches a neutral temperature of at least about 3,000 K to form an activated gas mixture or alternatively using a glow discharge to activate the gas, and thereafter contacting said activated gas mixture with the surface deposits and thereby removing at least some of said surface deposits.

### BRIEF DESCRIPTION OF THE DRAWINGS

FIG. 1 is a schematic diagram of an apparatus useful for carrying out the present process.

FIG. 2 is a plot of silicon nitride etching rate for various compositions as a process chamber pressure of 5 torr and different wafer temperatures

FIG. 3 is a plot of silicon nitride etching for various compositions at a process chamber pressure of 2 torr, as a function of plasma source pressure.

FIG. 4 is a plot of silicon nitride etching for various compositions at a process chamber pressure of 3 torr, as a function of plasma source pressure.

FIG. 5 is a plot of silicon nitride etching for various compositions at a process chamber pressure of 5 torr, as a function of plasma source pressure.

FIG. 6 is a plot of silicon nitride etching at different temperatures at a process chamber pressure of 2 torr, as a function of plasma source pressure.

FIG. 7 is a plot of silicon nitride etching at different temperatures at a process chamber pressure of 3 torr, as a function of plasma source pressure

FIG. 8 is a plot comparing silicon nitride etching rates using C₂F₆ and C₄H₈ as the fluorocarbon at a remote chamber pressure of 2 torr.

FIG. 9 is a plot comparing silicon nitride etching rates using C₂F₆ and C₄H₈ as the fluorocarbon at a process chamber pressure of 3 torr.

FIG. 10 is a plot comparing silicon nitride etching rates using C₂F₆, oxygen, and NF₃ at a flow rate of 4800 sccm at a process chamber pressure of 5 torr at different wafer temperatures.

### DETAILED DESCRIPTION OF THE INVENTION

Surface deposits removed with this invention comprise those materials commonly deposited by chemical vapor deposition (CVD) or plasma-enhanced chemical vapor deposition (PECVD) or similar processes. Such materials include nitrogen-containing deposits. Such deposits include, without limitation, silicon nitride, silicon oxynitride, silicon carbonitride (SiCN), silicon boronitride (SiBN), and metal nitrides, such as tungsten nitride, titanium nitride or tantalum nitride, or PECVD OSG including Black Diamond (Applied Materials), Coral (Novellus Systems) and Aurora (ASM International). In one embodiment of the invention, a preferred surface deposit is silicon nitride.

In one embodiment of the invention surface deposits are removed from the interior of a process chamber that is used in fabricating electronic devices. Such a process chamber could be a CVD chamber or a PECVD chamber. Other embodiments of the invention include, but are not limited to, removing surface deposits from metals, the cleaning of plasma etching chambers and removal of N-containing thin films from a wafer.

In one embodiment, the process of the present invention involves an activating step wherein a cleaning gas mixture will be activated in a remote chamber. Activation may be accomplished by any means allowing for the achievement of dissociation of a large fraction of the feed gas, such as: radio frequency (RF) energy, direct current (DC) energy, laser illumination, and microwave energy. One embodiment of this invention is using transformer coupled inductively coupled lower frequency RF power sources in which the plasma has a torroidal configuration and acts as the secondary of the transformer. The use of lower frequency RF power allows the use of magnetic cores that enhance the inductive coupling with respect to capacitive coupling; thereby allowing the more efficient transfer of energy to the plasma without excessive ion bombardment which limits the lifetime of the remote plasma source chamber interior. Typical RF power used in this invention has a frequency lower than 1000 kHz. In another embodiment of this invention the power source is a remote microwave, inductively, or capacitively coupled plasma source. In yet another embodiment of the invention, the gas is activated using a glow discharge.

Activation of the cleaning gas mixture uses sufficient power for a sufficient time to form an activated gas mixture. In one embodiment of the invention the activated gas mixture has a neutral temperature of at least about 3,000 K. The neutral temperature of the resulting plasma depends on the power and the residence time of the gas mixture in the remote chamber. Under certain power input and conditions, neutral temperature will be higher with longer residence times. In one embodiment of the invention, a preferred neutral temperature of the activated gas mixture is over about 3,000 K. Under appropriate conditions (considering power, gas composition, gas pressure and gas residence time), neutral temperatures of at least about 6,000 K may be achieved.

The activated gas may be formed in a separate, remote chamber that is outside of the process chamber, but in close proximity to the process chamber. In this invention, remote chamber refers to the chamber other than the cleaning or process chamber, wherein the plasma may be generated, and process chamber refers to the chamber wherein the surface deposits are located. The remote chamber is connected to the process chamber by any means allowing for transfer of the activated gas from the remote chamber to the process chamber. For example, the transport passage may comprise a short connecting tube and a showerhead of the CVD/PECVD process chamber. The remote chamber and means for connecting the remote chamber with the process chamber are constructed of materials known in this field to be capable of containing activated gas mixtures. For instance, aluminum and anodized aluminum are commonly used for the chamber components. Sometimes Al₂O₃ is coated on the interior surface to reduce the surface recombination. In other embodiments of the invention, the activated gas mixture may be formed directly in the process chamber.

The gas mixture that is activated to form the activated gas comprises an oxygen source, an inorganic fluorine source, a fluorocarbon and a nitrogen source. Typical inorganic fluorine sources include NF₃ and SF₆. A fluorocarbon of the invention is herein referred to as a compound comprising of C and F. In one embodiment of the invention, a fluorocarbon is a perfluorocarbon. A perfluorocarbon compound as referred to in this invention is a compound consisting of C, F and optionally oxygen. Such perfluorocarbon compounds include, but are not limited to tetrafluoromethane, hexafluoroethane, octafluoropropane, hexafluororcyclopropane, decafluorobutane, octafluorocyclobutane and octafluorotetrahydrofuran. Without wishing to be bound by any particular theory, applicant believes that the fluorocarbon of the gas mixture serves as a source of carbon atoms in the activated gas mixture. Typical nitrogen sources include molecular nitrogen (N₂) and NF₃. When NF₃ is the inorganic fluorine source, it can also serve as the nitrogen source. Typical oxygen sources include molecular oxygen (O₂). When the fluorocarbon is octafluorotetrahydrofuran, that can also serve as the oxygen source. In one embodiment of the invention, the oxygen:fluorocarbon molar ratio is at least 0.75:1. In another embodiment of the invention, the oxygen:fluorocarbon molar ratio is at least 1:1. Depending on the fluorocarbon chosen, in other embodiments of the invention the oxygen:fluorocarbon molar ratio may be 2:1.

In one embodiment of the invention, the percentage on a molar basis of inorganic fluorine source in the gas stream is from about 50% to about 98%. In another embodiment of the invention the percentage on a molar basis of inorganic fluorine source in the gas stream is from about 60% to about 98%. In yet another embodiment of the invention, the percentage on a molar basis of inorganic fluorine source in the gas stream is from about 70% to about 90%.

The gas mixture that is activated to form the activated gas mixture of the invention may further comprise a carrier gas. Examples of suitable carrier gasses include noble gasses such as argon and helium.

In an embodiment of the invention, the temperature in the process chamber during removal of the surface deposits may be from about 50° C. to about 150° C.

The total pressure in the remote chamber during the activating step may be between about 0.5 torr and about 15 torr using the Astron source. The total pressure in the process chamber may be between about 0.5 torr and about 15 torr. With other types of remote plasma sources or in situ plasmas the pressure ranges.

It has been found in this invention that the combination of oxygen, an inorganic fluorine source, a nitrogen source, and a fluorocarbon results in significantly higher etching rates of nitride films such as silicon nitride. These increases also provide lower sensitivity of the etch rate to variations in source gas pressure, chamber pressure and temperature.

The following Examples are meant to illustrate the invention and are not meant to be limiting.

### EXAMPLES

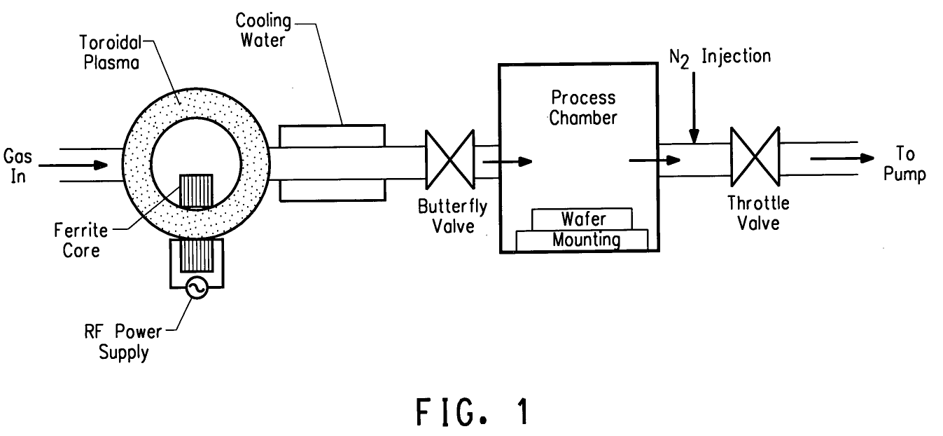

FIG. 1 shows a schematic diagram of the remote plasma source and apparatus used to measure the etching rates, plasma neutral temperatures, and exhaust emissions. The remote plasma source is a commercial toroidal-type MKS ASTRON® ex reactive gas generator unit make by MKS Instruments, Andover, Mass, USA. The feed gases (e.g. oxygen, fluorocarbon, NF₃ and carrier gas) were introduced into the remote plasma source from the left, and passed through the toroidal discharge where they were discharged by the 400 kHz radio-frequency power to form an activated gas mixture. The oxygen is manufactured by Airgas with 99.999% purity. The fluorocarbon in the examples is either Zyron® 8020 manufactured by DuPont with a minimum 99.9 vol. % of octafluorocyclobutane or Zyron® 116 N5 manufactured by DuPont with a minimum 99.9 vol. % of hexafluoroethane. The NF₃ gas is manufactured by DuPont with 99.999% purity. Argon is manufactured by Airgas with a grade of 5.0. Typically, Ar gas is used to ignite the plasmas, after which time flows for the feed gases were initiated, after Ar flow was halted. The activated gas mixture then is passed through an aluminum water-cooled heat exchanger to reduce the thermal loading of the aluminum process chamber. The surface deposits covered wafer was placed on a temperature controlled mounting in the process chamber. The neutral temperature is measured by Optical Emission Spectroscopy (OES), in which rotovibrational transition bands of diatomic species like C₂ and N₂ are theoretically fitted to yield neutral temperature. See also B. Bai and H Sawin, Journal of Vacuum Science & Technology A 22 (5), 2014 (2004), which is herein incorporated by reference. The etching rate of surface deposits by the activated gas is measured by interferometry equipment in the process chamber. N₂ gas is added a the entrance of the exhaustion pump both to dilute the products to a proper concentration for FTIR measurement and to reduce the hang-up of products in the pump. FTIR was used to measure the concentration of species in the pump exhaust.

### Example 1

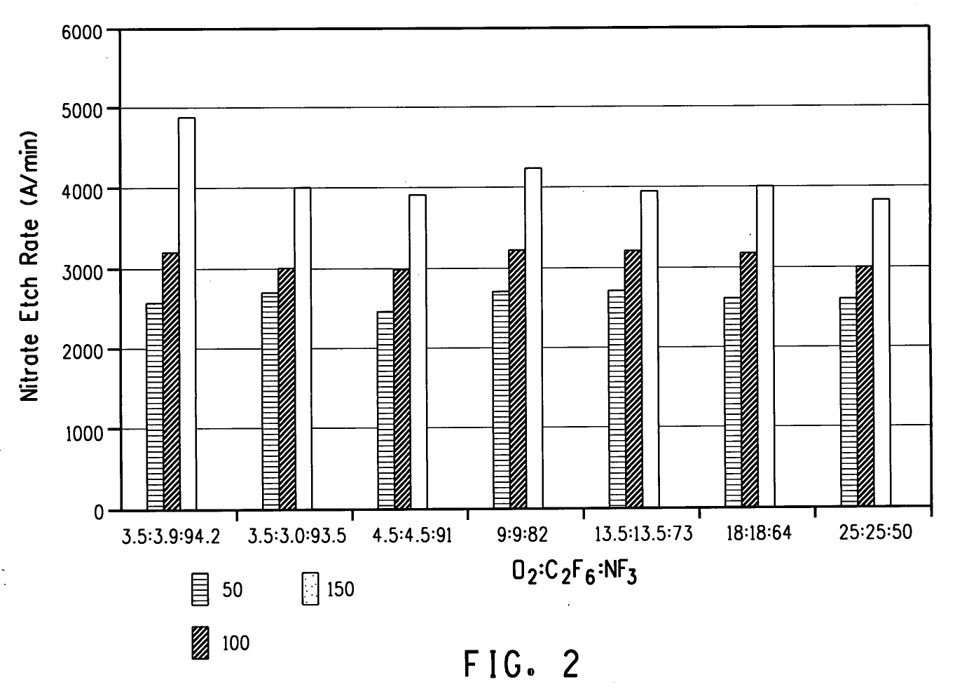

This example illustrates the effect of the addition of fluorocarbon on the silicon nitride etch rate in NF₃ systems with oxygen at different gas compositions and different wafer temperatures. In this experiment, the feed gas was composed of NF₃, with oxygen and C₂F₆. Process chamber pressure was 5 torr. Total gas flow rate was 1700 sccm, with flow rates for the individual gases set proportionally as required for each experiment. By way of illustration, in the experiment with 9% oxygen, 9% C₂F₆, and 82% NF₃, the oxygen flow rate was 150 sccm, the C₂F₆ flow rate was 150 sccm, and the NF₃ flow rate was 1400 sccm. The feeding gas was activated by the 400 kHz 5.9˜8.7 kW RF power to a neutral temperature of more than 3000 K. the activated gas then entered the process chamber and etched the silicon nitride surface deposits on the mounting with the temperature controlled at 50° C. As shown in FIG. 2, when 3.5 mole percent oxygen and 2.3 mole percent fluorocarbon were added, the etch rate was over 2500 A/min, and exhibited low sensitivity to variations in the amounts of fluorocarbon and oxygen addition. The same phenomena were observed in all wafer temperatures tested: 50° C., 100° C. and 150° C.

### Example 2

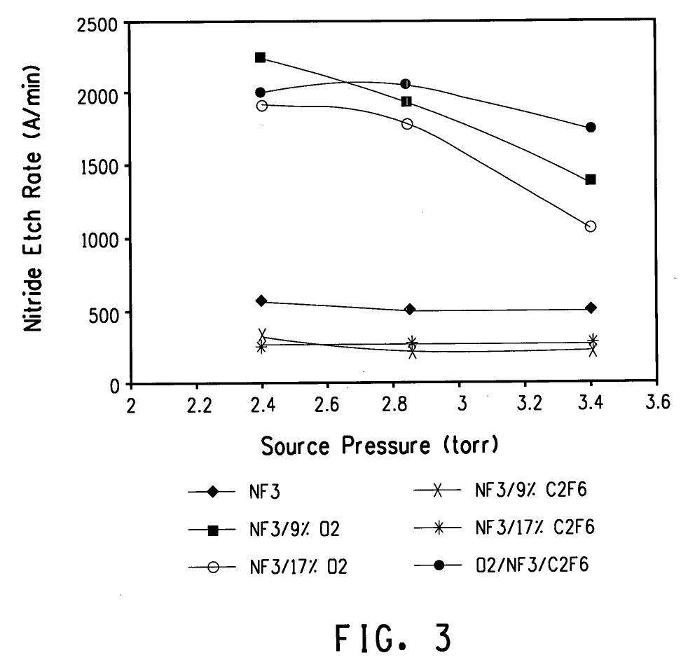

This example illustrated the effect of the addition of fluorocarbon on the silicon nitride etch rate in NF₃ systems with oxygen and the reduced effect of source pressure on etch rate. The results are illustrated in FIG. 3. In this experiment, the feed gas was composed of NF₃, optionally with O₂ and optionally with C₂F₆. Process chamber pressure was 2 torr. Total gas flow rate was 1700 sccm, with flow rates for the individual gases set proportionally as required for each experiment. By way of illustration, in the experiment with 9% oxygen and 91% NF₃, the NF₃ flow rate was 1550 sccm and the oxygen flow rate was 150 sccm. The feeding gas was activated by the 400 kHz 5.0˜9.0 kW RF power to a neutral temperature of more than 3000 K. The activated gas then entered the process chamber and etched the silicon nitride surface deposits on the mounting with the temperature controlled at 50° C. As shown in FIG. 3, when 9 mole percent fluorocarbon and 9 mole percent oxygen were added to NF₃, high etching rates for silicon nitride were obtained, and the rate exhibited very low sensitivity to variations in source pressure.

### Example 3

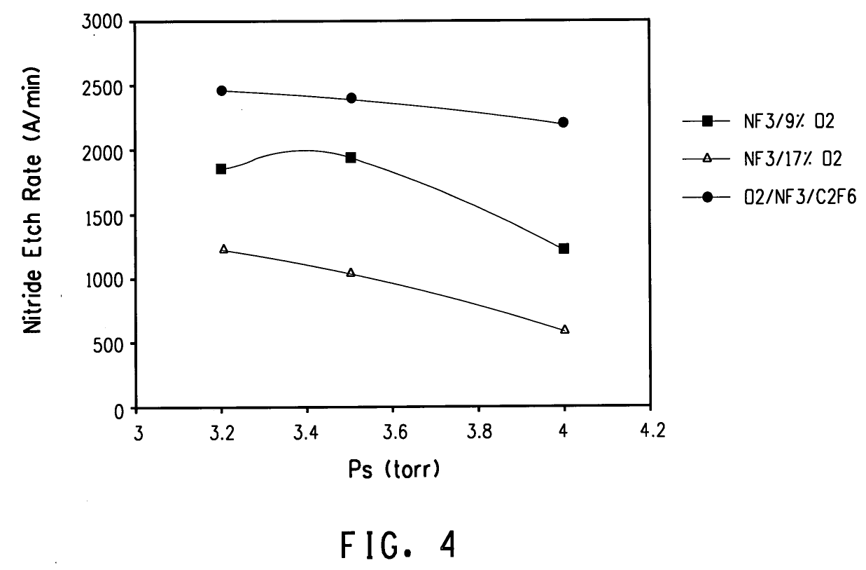

This example illustrates the effect of the addition of C₂F₆ on the silicon nitride etch rate in mixtures of NF₃ and oxygen with a chamber pressure of 3.0 torr. Total gas flow rate was 1700 sccm. The results are illustrated in FIG. 4. The feeding gas was activated by the 400 kHz 4.6 Kw RF power to a neutral temperature of more than 3000 K. As the results indicate, when 9 mole percent C₂F₆ is added to the feed gas, i.e. the feed gas mixture was composed of 9 mole percent C₂F₆, 9 mole percent oxygen and 82 mole percent NF₃, the etching rate of silicon nitride increase to from about 2200 A/min to about 2450 A/min, and exhibited lower variation with variations in source pressure.

### Example 4

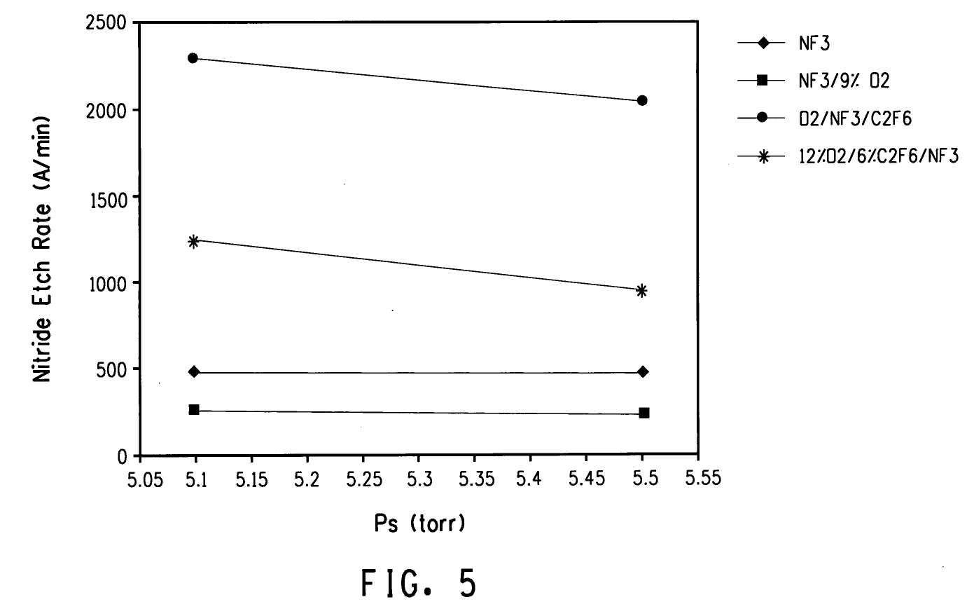

This example illustrates the effect of the addition of C₂F₆ on the silicon nitride etch rate in mixtures of NF₃ and oxygen and variations in the molar ratio of C₂F₆ to oxygen with a chamber pressure of 5.0 torr. Total gas flow rate was 1700 sccm. The results are illustrated in FIG. 5. The feeding gas was activated by the 400 kHz RF power to a neutral temperature of more than 3000 K. It was found that the highest etch rate and low variation with variations in source pressure were obtained with an oxygen to C₂F₆ ratio of 1:1. That is, with a feed gas mixture of 9 mole percent C₂F₆, 9 mole percent oxygen, and 82 mole percent NF₃. Silicon nitride etch rates with this feed gas composition were from about 2050 to about 2300 A/min compared to from about 950 A/min to about 1250 A/min with a oxygen:fluorocarbon ratio of 2:1.

### Example 5

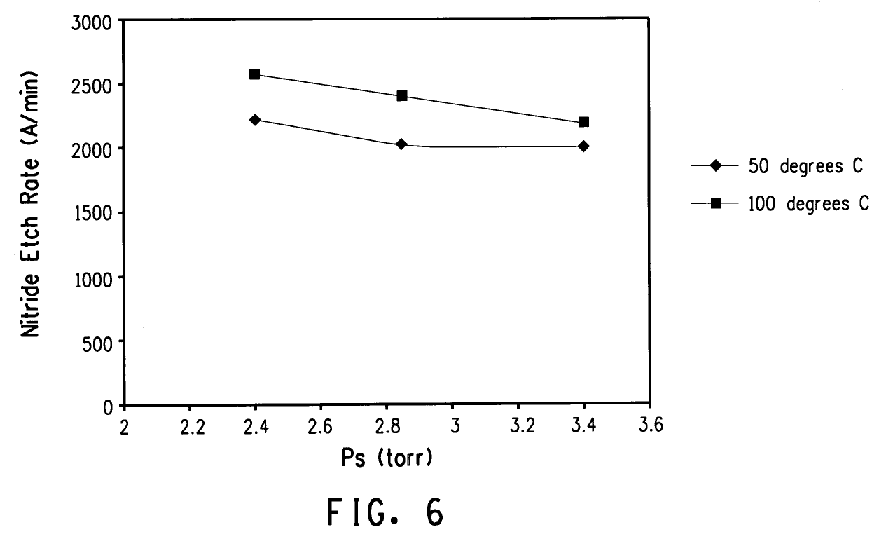

This example illustrates the effect of process chamber temperature on silicon nitride etch rate using a feed gas mixture of 9 mole percent C₂F₆, 9 mole percent oxygen, and 82 mole percent NF₃ and a chamber pressure of 2 torr. Total gas flow rate was 1700 sccm. The results are illustrated in FIG. 6. The feeding gas was activated by the 400 kHz 6.0˜6.6 kW RF power to a neutral temperature of more than 3000 K. It was found that etch rate increases somewhat as the chamber temperature is increased from 50° C. to 100° C. No significant difference is variation with changes is source pressure was observed.

### Example 6

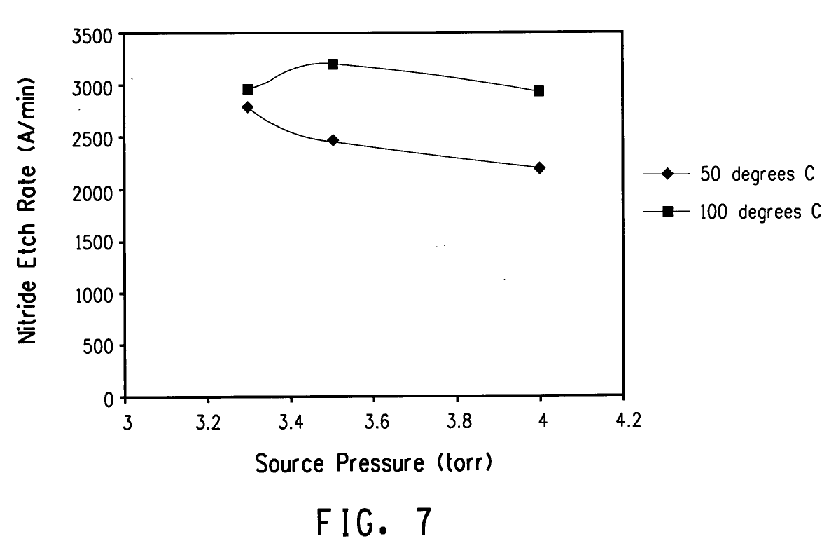

This example illustrates the effect of process chamber temperature on silicon nitride etch rate using a feed gas mixture of 9 mole percent C₂F₆, 9 mole percent oxygen, and 82 mole percent NF₃ and a chamber pressure of 3 torr. Total gas flow rate was 1700 sccm. The results are illustrated in FIG. 7. The feeding gas was activated by the 400 kHz 6.7˜7.2 kW RF power to a neutral temperature of more than 3000 K. It was found that etch rate increases somewhat as the chamber temperature is increased from 50° C. to 100° C. At 100° C. there is little variation in etch rate with changes in source pressure.

### Example 7

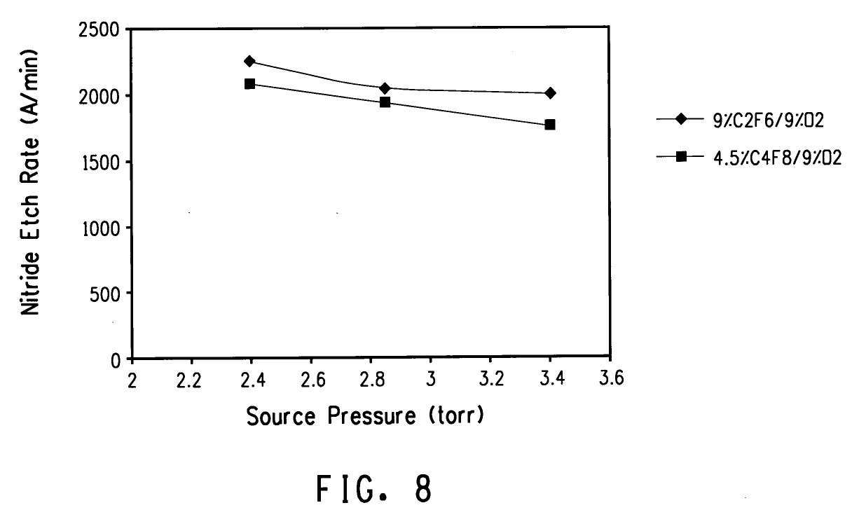

This example compares nitride etching using octafluorocyclobutane as the fluorocarbon. In this example, the feed gas mixtures were either 9 mole percent C₂F₆, 9 mole percent oxygen, and 82 mole percent NF₃, or 4.5 mole percent C₄F₈, 9 mole percent oxygen, and 86.5 mole percent NF₃. Total gas flow rate was 1700 sccm. The chamber pressure was 2 torr. The feeding gas was activated by the 400 kHz 6.5 Kw RF power to a neutral temperature of more than 3000 K. The results are illustrated in FIG. 8. Octafluorocyclobutane exhibited similar etching performance compared to hexafluoroethane with respect to etch rate, and variation with variations in source pressure.

### Example 8

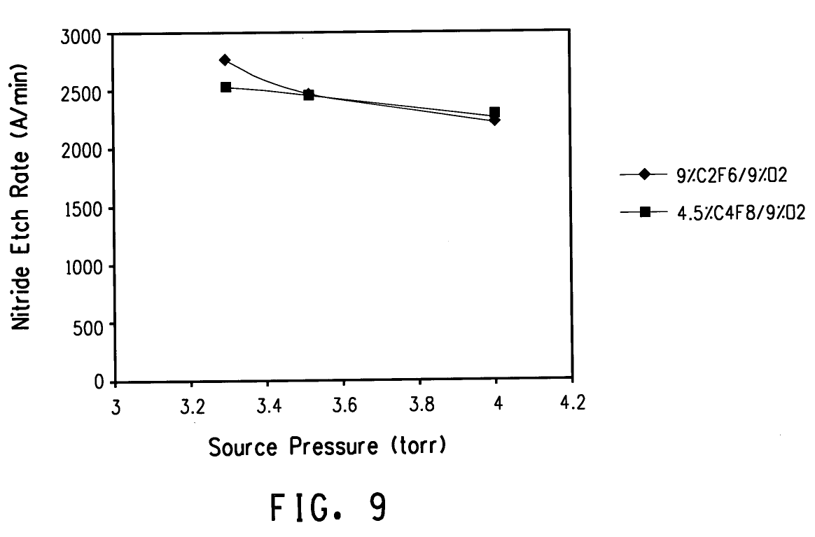

This example compares nitride etching using octafluorocyclobutane as the fluorocarbon. In this example, the feed gas mixtures were either 9 mole percent C₂F₆, 9 mole percent oxygen, and 82 mole percent NF₃, or 4.5 mole percent C₄F₈, 9 mole percent oxygen, and 86.5 mole percent NF₃. The chamber pressure was 3 torr. Total gas flow rate was 1700 sccm. The feeding gas was activated by the 400 kHz 6.9 Kw RF power to a neutral temperature of more than 3000 K. The results are illustrated in FIG. 9. Octafluorocyclobutane exhibited similar etching performance compared to hexafluoroethane with respect to etch rate, and variation with variations in source pressure.

### Example 9

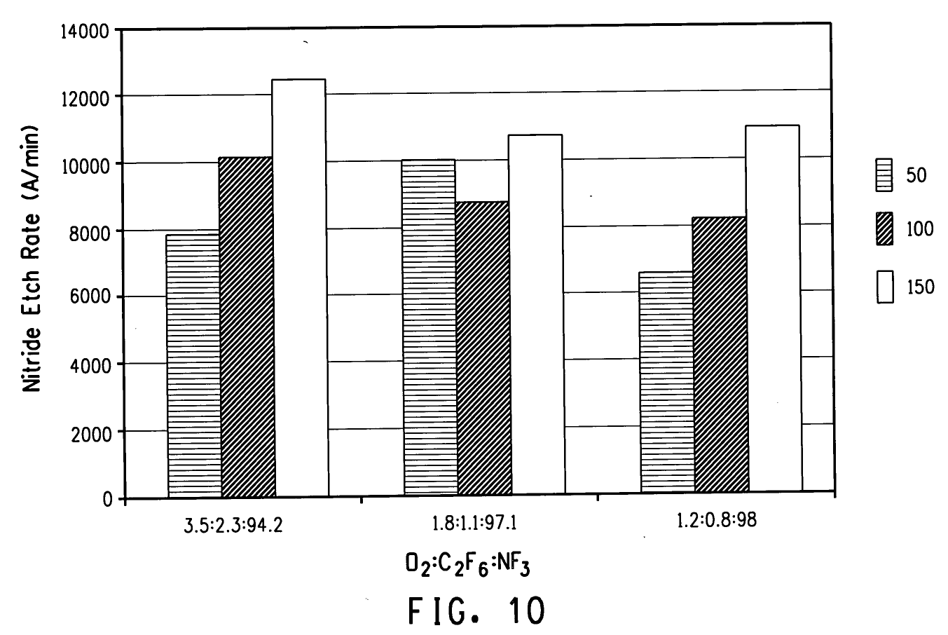

This example illustrates the effect of the addition of fluorocarbon on the silicon nitride etch rate in NF₃ systems with oxygen at different gas compositions and different wafer temperatures. In this experiment, the feed gas was composed of NF₃, with oxygen and C₂F₆. Process chamber pressure was 5 torr. Total gas flow rate was 4800 sccm, with flow rates for the individual gases set proportionally as required for each experiment. By way of illustration, in the experiment with 1.8% oxygen, 1.1% C₂F₆, and 97.1% NF₃, the oxygen flow rate was 85 sccm, the C₂F₆ flow rate was 50 sccm, and the NF₃ flow rate was 4665 sccm. The feeding gas was activated by the 400 kHz 5.9-8.7 kW RF power to a neutral temperature of more than 3000 K. the activated gas then entered the process chamber and etched the silicon nitride surface deposits on the mounting with the temperature controlled at 50° C. As shown in FIG. 10, when 3.5 mole percent oxygen and 2.3 mole percent fluorocarbon were added, the etch rate was over 7500 A/min, and exhibited low sensitivity to variations in the amounts of fluorocarbon and oxygen addition. The same phenomena were observed in all wafer temperatures tested: 50° C., 100° C. and 150° C. Even at 1.2 mole % O₂ and 0.8 mole % C₂F₆, high etch rates were observed.

While specific embodiments of the invention have been shown and described, further modifications and improvements will occur to those skilled in the art. It is desired that it be understood, therefore, that the invention is not limited to the particular form shown and it is intended in the appended claims which follow to cover all modifications which do not depart from the spirit and scope of the invention.

What is claimed is:

1. A method for removing surface deposits, comprising:
(a) activating in a remote chamber a gas mixture comprising oxygen, a fluorocarbon, and NF₃, wherein the molar ratio of oxygen:fluorocarbon is at least about 0.75:1, and wherein the molar percentage of NF₃ in the said gas mixture is from about 50% to about 98%,
(b) allowing said activated gas mixture to flow into a process chamber, and thereafter,
(c) contacting said activated gas mixture with the surface deposits and thereby removing at least some of said deposits.

2. The method of claim 1 wherein said process chamber is the interior of a deposition chamber that is used in fabricating electronic devices.

3. The method of claim 1 wherein the fluorocarbon is a perfluorocarbon.

4. The method of claim 1 wherein the fluorocarbon is selected from the group consisting of tetrafluoromethane, hexafluoroethane, octafluoropropane, perfluorotetrahydrofuran and octafluorocyclobutane.

5. The method of claim 3 wherein the fluorocarbon is hexafluoroethane.

6. The method of claim 3 wherein the fluorocarbon is octafluorocyclobutane.

7. The method of claim 1 wherein the said surface deposit a nitrogen-containing deposit.

8. The method of claim 1 wherein the said surface deposit is selected from the group consisting of silicon nitride, silicon oxynitride, silicon carbonitride, tungsten nitride, titanium nitride, and tantalum nitride.

9. The method of claim 7 wherein the said surface deposit is silicon nitride.

10. The method of claim 1 wherein the molar percentage of NF₃ is from about 60% to about 98% of the gas mixture.

11. The method of claim 1 wherein the molar percentage of NF₃ is from about 70% to about 90% of the gas mixture.

12. The method of claim 1 wherein the oxygen:fluorocarbon molar ratio is about 1:1.

13. The method of claim 1 wherein said gas mixture further comprises a carrier gas.

14. The method of claim 13 wherein said carrier gas is selected from the group consisting of argon and helium.

15. The method of claim 1 wherein the pressure in the process chamber is from about 0.5 torr to about 15 torr.

16. The method of claim 1 wherein the pressure in the remote chamber is from about 0.5 torr to about 15 torr.

17. The method of claim 16 wherein the pressure in the remote chamber is from about 2 torr to about 6 torr.

18. The method of claim 1 wherein said power is generated by an RF source, a DC source or a microwave source.

19. The method of claim 18 wherein said power is generated by an RF source.

20. A method for removing surface deposits comprising:
a.) activating in a process chamber a gas mixture comprising oxygen, a fluorocarbon, and NF₃, wherein the molar ratio of oxygen:fluorocarbon is at least about 0.75:1, and wherein the molar percentage of NF₃ in the said gas mixture is from about 50% to about 98%,
b.) contacting said activated gas mixture with the surface deposits and thereby removing at least some of said deposits.

21. A method as in claim 20 wherein said process chamber is the interior of a deposition chamber that is used in fabricating electronic devices.

22. The method of claim 20 wherein the fluorocarbon is a perfluorocarbon.

23. The method of claim 20 wherein the fluorocarbon is selected from the group consisting of tetrafluoromethane, hexafluoroethane, octafluoropropane, perfluorotetrahydrofuran and octafluorocyclobutane.

24. The method of claim 23 wherein the fluorocarbon is hexafluoroethane.

25. The method of claim 23 wherein the fluorocarbon is octafluorocyclobutane.

26. The method of claim 20 wherein the said surface deposit a nitrogen-containing deposit.

27. The method of claim 20 wherein the said surface deposit is selected from the group consisting of silicon nitride, silicon oxynitride, silicon carbonitride, tungsten nitride, titanium nitride, and tantalum nitride.

28. The method of claim 26 wherein the said surface deposit is silicon nitride.

29. The method of claim 20 wherein the molar ratio of oxygen:fluorocarbon is at least about 1:1.

30. The method of claim 20 wherein the molar percentage of NF₃ is from about 60% to about 98% of the gas mixture.

31. The method of claim 20 wherein the molar percentage of NF₃ is from about 70% to about 90% of the gas mixture.

32. The method of claim 20 wherein the oxygen:fluorocarbon molar ratio is about 1:1.

33. The method of claim 20 wherein said gas mixture further comprises a carrier gas.

34. The method of claim 33 wherein said carrier gas is selected from the group consisting of argon and helium.

35. The method of claim 20 wherein the pressure in the process chamber is from about 0.5 torr to about 15 torr.

34. A cleaning gas mixture comprising from about 50% to about 98% on a molar basis NF₃, an oxygen source and a fluorocarbon.

35. A cleaning gas mixture as in claim 34 wherein the oxygen source is molecular oxygen.

36. A cleaning gas mixture as in claim 34 wherein the fluorocarbon is a perfluorocarbon.

37. A cleaning gas mixture as in claim 36 wherein the perfluorocarbon is selected from the group consisting of tetrafluoromethane, hexafluoroethane, octafluoropropane, perfluorotetrahydrofuran and octafluorocyclobutane.

38. A cleaning gas mixture as in claim 36 wherein the perfluorocarbon is hexafluoroethane.

39. A cleaning gas mixture as in claim 36 wherein the perfluorocarbon is octafluorocyclobutane.

40. A cleaning gas mixture as in claim 35 wherein the oxygen:fluorocarbon ratio is at least about 0.75:1.0.

41. A cleaning gas mixture as in claim 35 wherein the oxygen:fluorocarbon ratio is at least about 1:1.
